(19) United States
(12) Patent Application Publication
(10) Pub. No.: US 2026/0080132 A1
(43) Pub. Date: Mar. 19, 2026

(54) ESTIMATING PRODUCTION PROFILES IN A MULTILATERAL WELL

(71) Applicant: Schlumberger Technology Corporation, Sugar Land, TX (US)

(72) Inventors: Saket Srivastava, Houston, TX (US); Agustin Gambaretto, Houston, TX (US); Kushagra Shresth, Pune (IN); Anna Danuta Sadowska, Cambridge (GB); Kim Fah Goh, Seria (BN); Andrew William Meredith, Cambridge (GB)

(21) Appl. No.: 18/884,574

(22) Filed: Sep. 13, 2024

(51) Int. Cl. G06F 30/28

(52) U.S. Cl. CPC G06F 30/28

(57) ABSTRACT

A production digital twin system may generate a model of a wellbore. A production digital twin system may use historical data, calibrating the model. A production digital twin system may receive an updated total production profile from one or more sensors located at a surface of the wellbore. A production digital twin system may update the model with the updated total production profile. A production digital twin system may generate, using the model, a virtual zonal production profile for each of the plurality of lateral production zones, the virtual zonal production profile based on a total production profile.

### BACKGROUND OF THE DISCLOSURE

Wellbores may be drilled into a surface location or seabed for a variety of exploratory or extraction purposes. For example, a wellbore may be drilled to access fluids, such as liquid and gaseous hydrocarbons, stored in subterranean formations and to extract the fluids from the formations. Wellbores used to produce or extract fluids may be lined with casing around the walls of the wellbore. A variety of drilling and methods may be utilized depending partly on the characteristics of the formation through which the wellbore is drilled, the fluid being produced, or other conditions in the subsurface.

A digital twin is a digital representation of a real system, with the aim to fully digitally simulate the real system. Conventionally, digital twin creation is a complex process that utilizes one or more models, including but not limited to simulation, surrogates, ML/AI, hybrids. Typically, this involves consolidating and listing available sources of information, creating orchestrators, designing, and implementing visualization, managing models, and ingesting data and configuring data binding. Such tasks are time-consuming, resulting bespoke solutions that are difficult to adapt and scale to other situations, including small changes to a particular situation.

### SUMMARY

In some aspects, the techniques described herein relate to a method for modeling wellbore production for a wellbore having a plurality of lateral production zones. A production digital twin system generates a model of a wellbore. Using historical data, the production digital twin system calibrates the model. The production digital twin system receives an updated total production profile from one or more sensors located at a surface of the wellbore. The production digital twin system updates the model with the updated total production profile. The production digital twin system generates, using the model, a virtual zonal production profile for each of the plurality of lateral production zones. The virtual zonal production profile is based on a total production profile.

In some aspects, the techniques described herein relate to a method for controlling production in a wellbore. A production digital twin system produces fluid using one or more valves located at a plurality of lateral production zones in the wellbore. The fluid is produced with total production profile. The production digital twin system measures an updated total production profile from one or more sensors. The updated total production profile includes a change in the total production profile. The production digital twin system updates a model of a wellbore with the updated total production profile. The production digital twin system generates, using the model, a plurality of virtual zonal production profiles for each of the plurality of lateral production zones. Based on the updated total production profile and the plurality of virtual zonal production profiles, the production digital twin system adjusts a valve setting of the one or more valves to adjust the total production profile.

This summary is provided to introduce a selection of concepts that are further described in the detailed description. This summary is not intended to identify key or essential features of the claimed subject matter, nor is it intended to be used as an aid in limiting the scope of the claimed subject matter. Additional features and aspects of embodiments of the disclosure will be set forth herein, and in part will be obvious from the description, or may be learned by the practice of such embodiments.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a representation of an example multilateral well that has been drilled in a subterranean formation, according to at least one embodiment of the present disclosure.

FIG. 2 is a schematic diagram of a production digital twin system, according to at least one embodiment of the present disclosure.

FIG. 3 is a representation of a production digital twin system, according to at least one embodiment of the present disclosure.

FIG. 4 is a schematic representation of a production digital twin system, according to at least one embodiment of the present disclosure.

FIG. 5 is a schematic representation of a production digital twin system, according to at least one embodiment of the present disclosure.

FIG. 6 is a schematic representation of a production digital twin system, according to at least one embodiment of the present disclosure.

FIG. 7 is a flowchart of a method for modeling wellbore production for a wellbore having a plurality of lateral production zones, according to at least one embodiment of the present disclosure.

FIG. 8 is a flowchart of a method for controlling production in a wellbore, according to at least one embodiment of the present disclosure.

FIG. 9 is a representation of a computing system, according to at least one embodiment of the present disclosure.

### DETAILED DESCRIPTION

This disclosure generally relates to devices, systems, and methods for generating a digital twin of a drilling production system and using the digital twin to estimate a production profile for each lateral production zone of a producing wellbore. Multilateral wells with electric submersible pumps and integrated completions are notoriously difficult to optimize or operate and can involve extensive testing processes to identify the flow characteristics of the wellbore, including the lateral flow characteristics of the lateral production zones of the wellbore. Ongoing production may result in changing conditions, resulting in frequent retests and re-configurations of the inflow control valves (ICVs) due to changes in production conditions, such as a change in the water cut (e.g., a gradual water cut increase over time, an acute water cut change). Furthermore, live testing of downhole conditions at the ICVs may not be possible or practical due to conditions at the ICVs and/or in the wellbore. For human operators, estimating the zonal production profiles of the wellbores is time-consuming and challenging.

In accordance with at least one embodiment of the present disclosure, a production estimator may generate a digital twin of the production of a multilateral well. The digital twin may be based on a model of the multilateral well. The model may include physical properties of the multilateral well, including wellbore details (e.g., depth, diameter, formation, casing), production equipment details (e.g., ICVs, packers, electric submersible pumps), fluid flow details (e.g., total flow rate, partial flow rate of lateral production zones, total pressure, partial pressure of lateral production zones, total water cut, partial water cut of lateral production zones), reservoir pressure of lateral production zones, any other physical properties, and combinations thereof. The model may provide estimates (e.g., virtual measurements) of wellbore properties. For example, the model may provide virtual measurements of the partial contributions of the lateral production zones of the wellbore to the total production profile of the wellbore (e.g., virtual zonal production profiles).

The model may be calibrated offline prior to implementation of the digital twin. For example, the model may be calibrated based on historical data, including historical data for the target wellbore and/or historical data for other wellbores. The model may be calibrated such that, based on a production profile measured at a surface location, the model may output the partial contributions of the lateral production zones of the wellbore to the total production profile. In some embodiments, the model may be calibrated to minimize an error function based on water cut, production index, reservoir pressure, and so forth. This calibrated model may then be used to optimize certain portions of the wellbore production, such as optimizing one or more lateral production zone production, reducing water cut, increasing overall production, and so forth.

In some embodiments, the model may be recalibrated in real-time. For example, the model may receive actual measurements of the production profiles at the surface and be recalibrated based on the actual measurements.

The calibrated model may be updated with current wellbore measurements. For example, the total production profile may receive as input an updated total production profile, different than the total production profile used to calibrate the model. When the calibrated model is updated, the model may then provide virtual measurements of the zonal production profile (e.g., virtual zonal production profiles) for the lateral production zones of the wellbore. For example, the virtual measurements may include virtual zonal production profiles of each of the lateral production zones of the wellbore.

In accordance with at least one embodiment of the present disclosure, an optimizer may adjust one or more operating parameters of the production system of the wellbore based on the virtual measurements from the model. For example, the optimizer may identify that one or more of the lateral production zones of the wellbore has a production profile that is outside of a threshold production profile. The optimizer may adjust the operating parameters of the production system, such as the valve settings of the ICVs and/or the pump settings of the electric submersible pump, to return the production profile to within the threshold range. In some embodiments the optimizer may manipulate the model to identify how the change to the operating parameters will impact the total production profile and/or the zonal production profiles. The optimizer may optimize the operating parameters of the production system based on valve positions, valve positions and pump setting, or valve positions, pump settings, and wellhead pressure. In this manner, the optimizer may maintain the production of the wellbore within a desired range.

The digital twin, including the calibrated model, the estimator, and the optimizer, may be maintained on an edge server. Maintaining the digital twin on the edge server may facilitate increase responsiveness for virtual measurements and/or a reduced latency in receiving the measurements. In this manner, the digital twin may result in improved responsiveness to changing conditions at the wellbore, thereby improving the responsiveness of the production system to changes.

As illustrated by the foregoing discussion, the present disclosure utilizes a variety of terms to describe features and advantages of the multilateral well digital twin. Additional detail is now provided regarding the meaning of such terms. For example, as used herein, the term “digital twin” refers to a digital representation of a physical asset. In particular, the term “digital twin” can include a digital representation of one or more elements of a physical asset, such as a process, a device or piece of equipment, flow of material through the physical asset, the physical arrangement of the physical asset, and so forth. To illustrate, a digital twin may include one or more models, simulations, or other digital representations of the physical asset.

The digital twin may generate one or more outputs. The outputs of the digital twin may be based on the elements the physical asset, including, but not limited to, resource consumption (e.g., electricity, fuel, materials) quantity and/or rate, resource generation (e.g., oil, gas) quantity and/or rate, waste generation (e.g., carbon dioxide, cuttings) quantity and/or rate, cost, profit, equipment wear and tear, any other output, and combinations thereof. The digital twin may include various parameters (and various relationships between the parameters) that generate the digital representation of the physical asset. Adjusting the parameters of the digital twin may result in changes to the output of the digital twin. As discussed in further detail herein, one or more of the parameters may be bound to a measurable input parameter or operating parameter that an operator may change to change the output of the physical asset. In accordance with at least one embodiment of the present disclosure, an evergreen digital twin may be a digital twin that is maintained up-to-date based on physical measurements measured by a sensor at the associated physical asset.

As used herein, a “physical asset” is a real-world element that has one or more measurable or quantifiable properties. For example, a physical asset may include a physical facility, unit of equipment, equipment set, tool, structure, process, fluid flow path, any other physical element, and combinations thereof. As a non-limiting example, a fluid flow path may include any fluid flow path and the associated piping, valves, pumps, storage tanks, and sensors, such as a drilling fluid flow path, an oil and gas production fluid flow path, coolant fluid flow, gas fluid flow paths, any other fluid flow paths, and combinations thereof.

As used herein, a static parameter may be a parameter of a digital twin (or a model or process underlying the digital twin) that is not changed during updating of the digital twin. For example, a static parameter may include one or more variables, constants, connections, or other element of a model or process that maintains stable operation of the digital twin.

As used herein, a tuned parameter may be a parameter of a digital twin (or a model or process underlying the digital twin) that is changed during updating of the digital twin. For example, the tuned parameters may be bound to one or more sensor measurements. In some examples, the tuned parameters may be bound to an input value, such as an operating state of a unit of equipment. Changing the tuned parameters may result in a change in the output of the digital twin. In some embodiments, changing the tuned parameters may not change the static parameters, or may not change the stability of the digital twin based on the interplay between the static parameters and the tuned parameters.

As used herein, an “edge network” may refer to an extension of the cloud located locally remote from a primary cloud server or server farm. The edge network may refer to one or more devices that provide connectivity to devices and/or services on a datacenter within a cloud computing system framework. An edge network may provide local cloud computing services on hardware similar configurations to the cloud network without requiring that the local hardware communicate with internal components of the cloud computing infrastructure. Indeed, edge networks provide virtual access points that enable more direct communication with components of the cloud computing system than another entry point, such as a public entry point, to the cloud computing system.

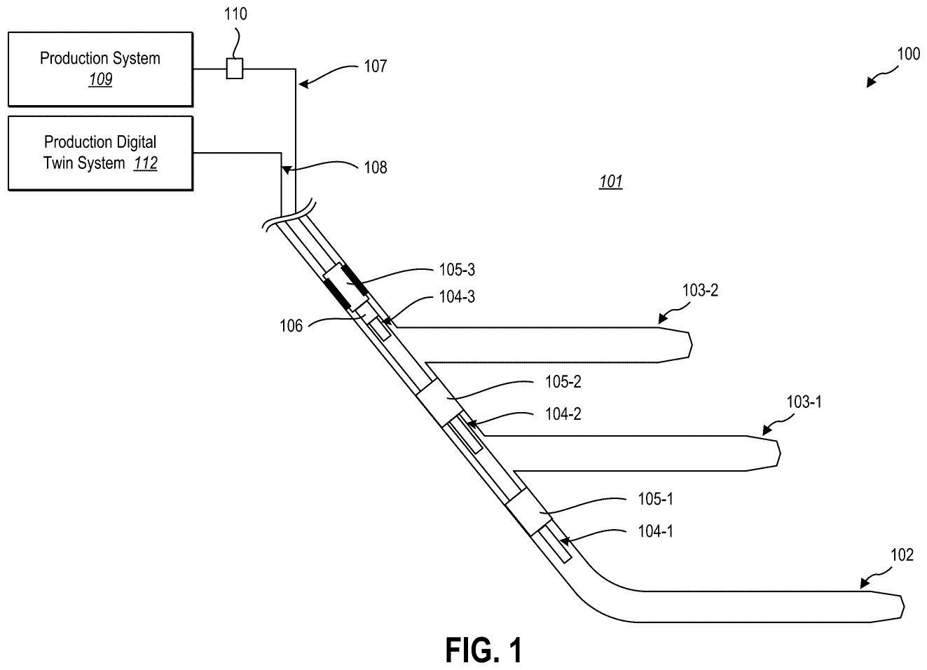

FIG. 1 is a representation of an example multilateral well 100 that has been drilled in a subterranean formation 101, in accordance with at least one embodiment of the present disclosure. The multilateral well includes a main bore 102 and a plurality of lateral bores (collectively 103). In this particular example, two lateral bores (e.g., a first lateral bore 103-1 and a second lateral bore 103-2) are shown, but any number of lateral bores may be drilled or otherwise formed. Additionally, while the two lateral bores 103 are shown as being generally parallel and of the same length, this is for illustration only. One skilled in the art will appreciate in view of the disclosure herein that any number of laterals may be used, that the laterals may be oriented in any number of manners (e.g., at different azimuth and incline), and may have any number of different curvatures or lengths. The lateral bores 103 optionally intersect upper, intermediate, lower, or other producing zones in the subterranean formation.

In the multilateral well 100 of FIG. 1, the multilateral well (including the main bore 102, lateral bores 103, or any portions thereof) may be cased with a liner/casing, or may be an uncased openhole wellbore or portion thereof. The casing/liner may include production tubing is suspended inside the wellbore for recovery of fluids to the surface.

Inside the wellbore may be a production control tool including one or more ICVs (collectively 104) or other flow control apparatus. For instance, an ICV 104 may be positioned in the multilateral well 100 near each of the lateral bores 103. For example, a first ICV 104-1 may be positioned near the main bore 102, a second ICV 104-2 may be positioned near the first lateral bore 103-1, and a third ICV 104-3 may be positioned near the second lateral bore 103-2, although further valves may be located near other laterals or production zones. The ICVs 104 may be located at the location that the lateral bores 103 and/or the horizontal portion of the main bore 102 (which may be considered a lateral bore) intersect the main bore 102.

Each ICV 104 or other fluid flow control apparatus can have a same or similar configuration. For instance, the ICV 104 can include a generally cylindrical mandrel body having a central longitudinal bore extending therethrough, with threads or other connection devices on one end thereof for interconnection to production tubing or a production tool. A movable lateral access door in the mandrel body can selectively permit and prevent a service tool from laterally exiting the body therethrough and into a lateral wellbore, or selectively permit or prevent fluid from the wellbore (e.g., a nearby lateral) from entering the production tool, or partially restrict or admit fluid from the wellbore from entering the production tubing or production tool. The ICVs 104 may have multiple valve settings. Each of the valve settings for the ICVs 104 may vary the amount of fluid that may enter the production tool. A selectively operable ICV 104 may be used for regulating fluid flow between the outside of the body and the central bore. In an ICV 104 or other flow control apparatus, a door can include an opening in the body and a door or plug member. The door may be moved longitudinally or radially, and may be moved by one or more means (e.g., motor/actuator, pinion gear, screw gear, etc.).

One or more packers (collectively 105) may also be used in the production control tool. The packers 105 can be used to isolate fluid flow (e.g., between producing lateral production zones in the lateral bores 103 and provide a fluidic seal restricting or even preventing co-mingling flow of produced fluids through a wellbore annulus). In the illustrated embodiment, a first packer 105-1 is located between the lateral production zone of the main bore 102 and the first lateral bore 103-1 (e.g., above the first ICV 104-1), a second packer 105-2 is located between the first lateral bore 103-1 and the second lateral bore 103-2 (e.g., above the second ICV 104-2), and a third packer 105-3 is located above the second lateral bore 103-2 and the third ICV 104-3). This may isolate the production zones. In some embodiments, the multilateral well 100 may include fewer packers 105, which may isolate two lateral production zones at the same time (e.g., a single packer 105 located above the lateral portion of the main bore 102 and the first lateral bore 103-1).

In the embodiment shown, the multilateral well 100 includes an electric submersible pump 106 located at the top of the production zones. The electric submersible pump 106 may pump fluid produced by the production zones of the main bore 102 and the lateral bores 103 to the surface via a production line 107. The electric submersible pump 106 may send the production fluid to the surface, wherein the fluid will be collected and processed.

A communication link 108 (such as a conduit or cable) is shown extending from the production control tool to a surface system. The communication link 108 may be in communication with one or more of the electric submersible pump 106 or the ICVs 104. The surface system can include any number of components (e.g., fluid recovery systems, display systems, control systems, etc.). In one example, a control system includes data storage capability (e.g., data from historic or past wells, the current well, etc.), an adaptive algorithm as described herein, communications interfaces, and one or more processors, as discussed in further detail herein.

In accordance with at least one embodiment of the present disclosure, a production system 109 may receive the production fluid from the production line 107. The production system 109 may direct the production fluid to tanks, a pipeline, a refinery, or other storage and processing system. One or more sensors 110 may be located on the production line 107 or at the production system 109. The sensors 110 may measure a total production profile of the drilling fluid. For example, the sensors 110 may measure total production volume, water cut, pressure, and other properties of the total production profile. The sensors 110 may be located at any location in the multilateral well 100, including downhole hole in the production line 107, at the surface (e.g., at the wellhead), at any other location, and combinations thereof.

A production digital twin system 112 may generate a digital twin of the multilateral well 100. For example, as discussed in further detail herein, the production digital twin system 112 may calibrate a model of the multilateral well 100. The production digital twin system 112 may calibrate the model offline, or calibrate the model prior to implementing the digital twin. The production digital twin system 112 may input the total production profile measured by the sensors 110 into the digital twin to maintain the digital twin as an evergreen digital twin. The digital twin may output virtual measurements for elements of the multilateral well 100 that do not include any physical sensors. For example, the digital twin may output virtual measurements of the zonal production profile (e.g., a virtual zonal production profile) of the lateral production zones at the ICVs 104. For example, in the embodiment shown in FIG. 1, the production digital twin system 112 may generate virtual measurements including a first virtual zonal production profile of a first lateral production zone of the lateral portion of the main bore 102 at the first ICV 104-1, a second virtual zonal production profile of a second lateral production zone of the first lateral bore 103-1 at the second ICV 104-2, and a third virtual zonal production profile of a third lateral production zone of the second lateral bore 103-2 at the third ICV 104-3.

In accordance with at least one embodiment of the present disclosure, an optimizer may receive the virtual measurements from the production digital twin system 112 and adjust the operation of the ICVs 104, the electric submersible pump 106, and other elements of the multilateral well 100. For example, the optimizer may identify that one or more of the virtual zonal production profiles has moved outside of a threshold range for the production profile. Based on the zonal production profile, the optimizer may adjust the operating parameters (e.g., pump settings, valve position) of the elements of the multilateral well 100. In this manner, the optimizer may improve the operational efficiency of the multilateral well 100.

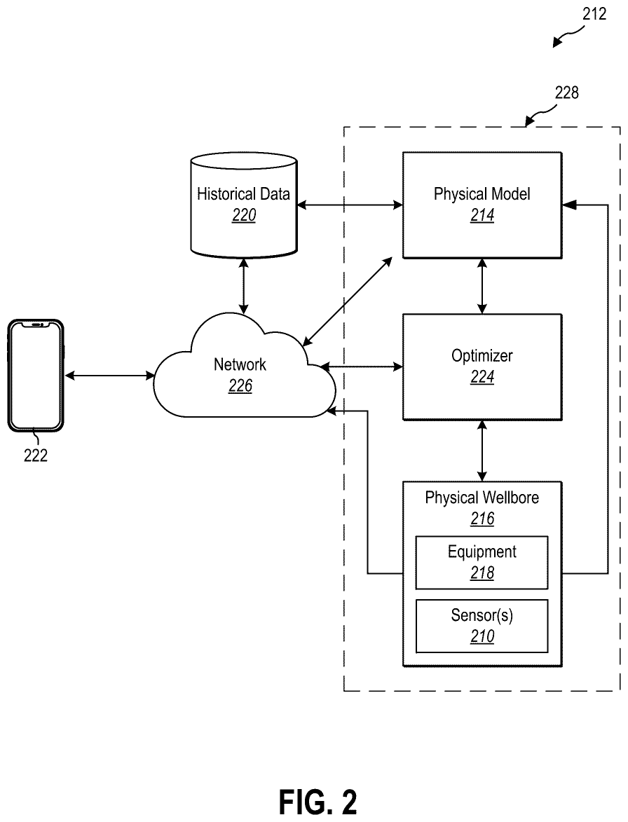

FIG. 2 is a schematic diagram of a production digital twin system 212, according to at least one embodiment of the present disclosure. The production digital twin system 212 may generate a digital twin of the production of a multilateral well system. To generate the digital twin, the production digital twin system 212 generates a model 214 of the multilateral well system. The model 214 may be built to simulate the operation of a physical wellbore 216, including various equipment 218 and their respective locations, physical parameters (e.g., hole diameter, depth, doglegs, casing), and other elements of the physical wellbore 216.

The model 214 may be calibrated using historical data 220. The historical data 220 may include production information measured by one or more sensors 210 located at a wellbore, including measured total production profiles, measured zonal production profiles, and other measured elements. In some embodiments, the historical data may include pressure sensors available along the tubular section, pressure temperature sensors available at equipment along the wellbore, and so forth. This may help to compensate for missing production profiles of lateral zones and/or individual wells in the situation of a pad having multiple wells. In some embodiments, the historical data may include the well test information to generate initial guesses for production profiles for when production data is not available during operation. In some embodiments, the historical data 220 may include equipment settings, such as the operating status of an electric submersible pump and/or the valve position of the ICVs. In some embodiments, the historical data 220 may include production information from the physical wellbore 216. In some embodiments, the historical data 220 may include production information from offset wellbores. In some embodiments, the offset wellbores may include wellbores at least partially in the same reservoir, formation, basin, or other similar geological feature. In some embodiments, the offset wellbores may include wellbores that include similar features, such as similar geometry (e.g., diameter, dogleg severity, depth) and/or similar equipment. In some embodiments, the offset wellbores may have few similarities with the physical wellbore 216.

To calibrate the model 214, a calibration engine may tune the relationships between parameters of the model 214 until the output virtual measurements (e.g., virtual zonal production profiles), based on input total production profile, are consistent with measured zonal production profiles from the historical data 220. In some embodiments, the parameters of the model 214 may be calibrated to minimize the error function, including the water cut alone, the water cut and PI, or the water cut, PI, and reservoir pressure. For example, the model 214 may be calibrated based on an error function that matches short-time-period rolling observations using an optimization method based on the moving horizon estimation approach. Calibrating the model 214 based on the error function may make the model 214 more representative of the actual conditions at the physical wellbore 216 and/or make the model 214 more robust.

When the model 214 is calibrated, the model 214 may be updated and/or further calibrated with updated measurements from the sensors 210 of the physical wellbore 216. For example, the sensors 210 may generate an updated total production profile based on new or updated measurements. The model 214 may be updated and/or further calibrated with the updated total production profile. In this manner, the production digital twin system 212 may generate an evergreen digital twin of the production of the multilateral well.

In some embodiments, a user may desire to identify the zonal production profiles of the various lateral production zones of the multilateral well. The user may request, at a user device 222, virtual measurements of the zonal production profiles for the lateral production zones of the multilateral well. The model 214 may include a production estimator that may estimate the properties of the wellbore at the various production zones. The model 214 may provide the zonal production profiles to the user at the user device 222. The user may utilize the zonal production profiles to identify the operating state of the wellbore and/or to make changes to the operating state of the wellbore. In this manner, the production digital twin system 212 may improve the efficiency and/or production volume of the multilateral well.

In some embodiments, the production digital twin system 212 may include an optimizer 224. The optimizer 224 may receive the virtual measurements (e.g., virtual zonal production profiles) from the model 214 and identify one or more changes to the virtual measurements. For example, the optimizer 224 may identify a change to the virtual zonal production profiles, and/or a change to the total production profiles. In some examples, the optimizer 224 may identify a change in the water cut. In some examples, the change in the water cut may be a gradual change in the water cut (e.g., a doubling of the water cut over 24 hours). In some examples, the change in the water cut may be an acute change in the water cut (e.g., a doubling of the water cut in 1 minute). In some embodiments, the optimizer 224 may attribute the change in the production conditions to a particular lateral production zone of the well. For example, the optimizer 224 may identify the change, and, based on the model 214, the optimizer 224 may identify that the change is a result of a change in the conditions of a particular lateral production zone.

In some embodiments, the optimizer 224 may identify, based on the measurements from the sensors 210, that an adjustment to an ICV or the ESP may improve the production of the multilateral well. The optimizer 224 may automatically make the change to the operating parameters of the multilateral well. In this manner, the production digital twin system 212 may automatically manage the production of the wellbore. Put another way, the optimizer 224 may optimize production of the physical wellbore 216 based on a change in conditions measured at the physical wellbore 216.

The elements of the production digital twin system 212 may be in communication over a network 226, such as the Internet. For example, one or more elements of the production digital twin system 212 may be stored at a remote server, such as a cloud server. The user may request, from the user device 222, the generation of the digital twin and/or the calibration of the model 214. The historical data 220 may be stored on the cloud. A stable version of the model 214 may be stored on the cloud and calibrated offline, or calibrated on the cloud prior to receiving live, up-to-date measurements from the physical wellbore 216.

In accordance with at least one embodiment of the present disclosure, at least a portion of the production digital twin system 212 may be operated on an edge network 228. The dotted line of the edge network 228 illustrates that the edge network 228 may include all or a portion of the elements and connections inside of the dotted line are located on or performed on the edge network 228. For example, the model 214, the optimizer 224, the connected portions of the physical wellbore 216 (e.g., the sensors 210, any other internet of things (IoT) device at the physical wellbore 216), and combinations thereof, may be located on the edge network 228.

Locating elements of the production digital twin system 212, including the digital twin of the physical wellbore 216 itself, on the edge network 228 may improve the reliability, speed, and/or accessibility of the results of the digital twin to the operator and other personnel at the physical wellbore 216. Wellbores are often located at remote locations, and access to the internet may be limited, unreliable, require specialized connections to the Internet, and combinations thereof. Locating the digital twin on the cloud may result in delays to generating the results, delays which may, at times, last hours or days. By locating the model 214 and the optimizer 224 on the edge network 228, the physical wellbore 216 may immediately receive the virtual measurements and control inputs. This may reduce lag time to change operating parameters of the physical wellbore 216.

In some embodiments, versions of the model 214, the optimizer 224, and the data collected by the sensors 210 may be stored on the cloud when these elements are connected to the internet. In this manner, the model 214, optimizer 224, and the sensors 210 may operate independently of the cloud and update when connected to the internet.

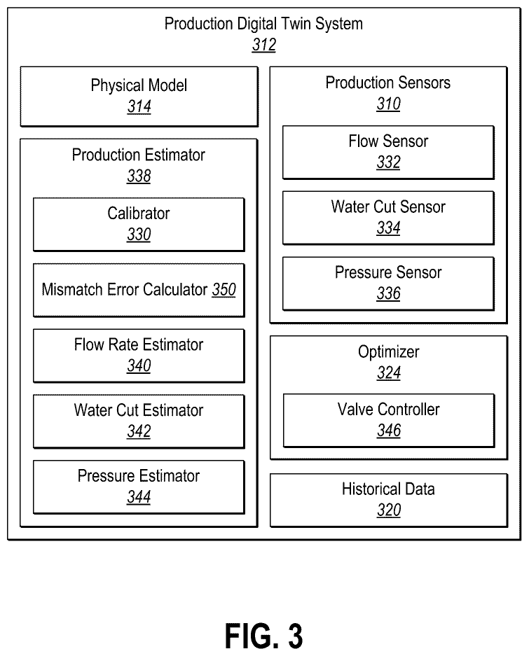

FIG. 3 is a representation of a production digital twin system 312, according to at least one embodiment of the present disclosure. Each of the components of the production digital twin system 312 can include software, hardware, or both. For example, the components can include one or more instructions stored on a computer-readable storage medium and executable by processors of one or more computing devices, such as a client device or server device. When executed by the one or more processors, the computer-executable instructions of the production digital twin system 312 can cause the computing device(s) to perform the methods described herein. Alternatively, the components can include hardware, such as a special-purpose processing device to perform a certain function or group of functions. Alternatively, the components of the production digital twin system 312 can include a combination of computer-executable instructions and hardware.

Furthermore, the components of the production digital twin system 312 may, for example, be implemented as one or more operating systems, as one or more stand-alone applications, as one or more modules of an application, as one or more plug-ins, as one or more library functions or functions that may be called by other applications, and/or as a cloud-computing model. Thus, the components may be implemented as a stand-alone application, such as a desktop or mobile application. Furthermore, the components may be implemented as one or more web-based applications hosted on a remote server. The components may also be implemented in a suite of mobile device applications or “apps.”

The production digital twin system 312 includes a model 314. As discussed herein, the model 314 may be built or generated using the physical parameters of the multilateral wellbore, including geometry, equipment, and so forth. After generating the model 314, a calibrator 330 may calibrate the model 314 based on historical data 320. As discussed herein, the calibrator 330 may calibrate the model 314 to minimize an error function calculated by a mismatch error calculator 350. The historical data 320 may include historical total production profiles, zonal production profiles, electric submersible pump settings, valve positions, any other historical data, and combinations thereof. The calibrator 330 may calibrate the model 314 in any manner. For example, the calibrator 330 may calibrate the model 314 based on observed conditions in relation to the error function.

In some embodiments, to calibrate the model 314, the calibrator 330 may provide an initial estimate (e.g., the values having the subscript sim in the error function) of the properties of the wellbore, including an initial input for various zonal parameters of each of the lateral production zones. For example, the calibrator 330 may provide an initial estimate for the water cut for each lateral production zone, the productivity index for each lateral production zone, the reservoir pressure for each lateral production zone, the bounds for optimization (e.g., of the water cut (+/−3%), the productivity index (+/−5%), the reservoir pressure (+/−1×10−5 psi)), any other property or characteristic, and combinations thereof. The calibration process may be iterative, and the initial estimates may be updated based on the input of the historical data 320.

The model 314 may include any type of model. For example, the model 314 may include a physics-based model of the wellbore. In some examples, the model 314 may include a computational fluid dynamics (CFD) model of fluid flow through the wellbore. In some examples, the model 314 may include a structural model of the wellbore. In some examples, the model 314 may include a 3-dimensional model of the wellbore. In some embodiments, the model 314 may include any combination of models discussed herein. In some embodiments, the model 314 may include one or more tuned parameters, such as the water cut for each lateral production zone, the productivity index for each lateral production zone, and the reservoir pressure for each lateral production zone.

The calibrator 330 may calibrate the model 314 offline. For example, the calibrator 330 may calibrate the model 314 on a cloud server. In some examples, the calibrator 330 may calibrate the model 314 prior to the model 314 being updated with measurements from one or more production sensors 310. In some embodiments, the calibrator 330 may calibrate the model 314 with historical measurements measured by the production sensors 310 and stored in the historical data 320. Calibrating the model 314 offline may utilize the greater processing resources of the cloud computing system without delaying operational decisions using localized processing resources or edge network processing resources.

The production digital twin system 312 may update and/or recalibrate the calibrated model 314 with updated measurements from the production sensors 310. The production sensors 310 may include any type of sensor used to collect production information. For example, the production sensors may include a flow sensor 332, a water cut sensor 334, and a pressure sensor 336. The flow sensor 332 may include a flow meter that may measure the total fluid flow out of the wellbore, or the total production fluid flow of the wellbore. The water cut sensor 334 may measure the total water cut of the production fluid, or the total percentage of water in the production fluid at the wellbore. The pressure sensor 336 may measure the pressure at the surface. In some embodiments, the pressure sensor 336 may measure the pump intake pressure and pump outtake pressure at the electric submersible pump. The production sensors 310 may include any other sensor. For example, the production sensors 310 may include a composition sensor, which may measure the hydrocarbon composition of the production fluid. In some embodiments, the production sensors 310 may measure or infer the productivity index for the wellbore. In some examples, the production sensors 310 may include a temperature sensor to measure the temperature of the production fluid.

The combination of parameters measured or inferred may be a production profile. The production profile may be a representation of the characteristics of the production fluid and the fluid flow of the production fluid. The production profile may include any characteristic, such as total flow rate, water cut, productivity index, pressure, any other characteristic, and combinations thereof. The production sensors 310 may measure or generate a total production profile, which may be the production profile of the fluid flow that exits the wellbore, or the combined production profile of all the fluid produced by the well.

The lateral production zones may include a zonal production profile. The zonal production profile may include the characteristics of the production fluid produced in a lateral production zone. The combination of zonal production profiles from the lateral production zones may result in the total production profile. In some embodiments, each lateral production zone may have a zonal production profile. In some embodiments, a combination of lateral production zones may have a zonal production profile. The zonal production profile may include the same or similar characteristics as the total production profile, including a partial fluid flow rate (e.g., the fluid flow rate out of the lateral production zone), a valve intake pressure (e.g., the downstream pressure of the ICV associated with the lateral production zone), a valve discharge pressure (e.g., the upstream pressure of the ICV associated with the lateral production zone), a partial productivity index (e.g., the productivity index associated with the lateral production zone), any other characteristic of the lateral production zones, and combinations thereof.

In some embodiments, the multilateral well production system may measure the production profile for individual lateral production zones or lateral bores. For example, to measure the production profile of a particular lateral production zone, the operator may close the ICVs associated with the other lateral production zones, preventing the ingress of production fluid from those zones. The multilateral well production system may measure the individual zonal production profile at the surface using the production sensors 310. This process may be repeated for each of the lateral production zones. In this manner, the multilateral well production system may identify or infer the zonal production profiles of each of the lateral production zones. The zonal production profiles, and the associated total production profile, may be stored in the historical data 320 and used to calibrate the model 314.

Measuring the zonal production profiles may be a time-consuming operation, resulting in decreased production for the multilateral well production system. The model 314 may be generated to identify the zonal production profiles based on the total production profile. For example, the calibrator 330 may calibrate the model 314 to generate virtual measurements for the zonal production profiles based on previously measured zonal production profiles and the associated total production profile. As discussed herein, the calibrator 330 may utilize the measured zonal production profiles from the target multilateral well and/or offset wellbores.

The production digital twin system 312 may include a production estimator 338. The production estimator 338 may generate estimates of the zonal production profiles for one or more of the lateral production zones downhole. For example, the production estimator 338 may generate estimates or virtual measurements for each of the elements of the zonal production profiles. To generate the virtual measurements, the production estimator 338 may receive updated measurements from the production sensors 310. For example, the production sensors 310 may generate an updated total production profile with up-to-date surface measurements. The production estimator 338 may update the model 314 with the updated total production profile. For example, the production estimator 338 may update or replace the inputs of the model 314 (e.g., the tuned parameters bound to the measurements of the production sensors 310) with the updated total production profile. The production estimator 338 may then generate the virtual measurements (e.g., using the static parameters of the model 314).

In some embodiments, the calibrator 330 may be part of the production estimator 338. For example, part of estimating the production of the system may include calibrating, using the calibrator 330, the model 314 to minimize the error function calculated by the mismatch error calculator 350.

The production estimator 338 may estimate any of the production parameters for the zonal production profile. For example, a flow rate estimator 340 may estimate the partial flow rate of a lateral production zone, a water cut estimator 342 may estimate the partial water cut of a lateral production zone, and a pressure estimator 344 may estimate the partial upstream ICV pressure and the partial downstream ICV pressure of a lateral production zone. This may result in the zonal production profiles for the lateral production zones.

The production digital twin system 312 may provide the zonal production profiles to any part of the multilateral well production system. For example, the production digital twin system 312 may provide the zonal production profiles to an optimizer 324. The optimizer 324 may control operation of one or more elements of the multilateral well production system. For example, the optimizer 324 may include a valve controller 346 that adjusts the valve position of one or more ICVs. This may change the production profile of the multilateral well. For example, changing the valve position of the ICVs may change the zonal production profiles and the resulting total production profile.

In some embodiments, the optimizer 324 may identify the valve positions that may increase the productivity of the multilateral well. For example, the optimizer 324 may adjust the parameters of the model 314 to identify how the changes may impact the zonal production profiles and the resulting total production profiles. In this manner, the optimizer 324 may increase the production of the multilateral well.

The production digital twin system 312 may monitor the total production profile and virtually measured zonal production profiles based on updated measurements from the production sensors 310 (e.g., the updated total production profile). In some embodiments, the optimizer 324 may detect a change in one or more production conditions (e.g., a change in one or more characteristics of the total production profile). In response to such a change, or after such change occurs, the optimizer 324 may apply an adaptive optimization process or algorithm. This can include any number of features or components. For instance, the valve controller 346 may re-configure one or more valves. Additionally, or alternatively, the detected change can be attributed to one or more specific laterals of a multilateral well and/or flow control can be optimized in one or more specific laterals. In the same or other embodiments, time, position, or both time and position for potential optimization can be identified. In this manner, the optimizer 324 may identify and adjust the operating conditions of the multilateral well production system to improve the production of the wellbore.

In some embodiments, the optimizer 324 calibrator 330 may optimize the model 314 for any condition. For example, the optimizer 324 calibrator 330 may optimize the model 314 to minimize the water cut. In some examples, the optimizer 324 calibrator 330 may optimize the model 314 to minimize the water cut and increase the productivity index. In some examples, the optimizer 324 calibrator 330 may optimize the model 314 to minimize the water cut, increase the productivity index, and/or optimize the ICV valve pressure for each lateral production zone.

In accordance with at least one embodiment of the present disclosure, the production digital twin system 312 may include a mismatch error calculator 350. The mismatch error calculator 350 may estimate and/or calculate a mismatch error based on the measured parameters compared to historical parameters. The mismatch error may be based on an error function that matches short-time-period rolling observations using an optimization method based on the moving horizon estimation approach, as illustrated below:

$$Error = Wa * \sqrt{{( {WC}_{sim} - {WC}_{hist} )}^{2}} + Wb * \sqrt{{( {Q}_{sim} - {Q}_{hist} )}^{2}} + Wc * \sqrt{{( {PIP}_{sim} - {PIP}_{hist} )}^{2}} + Wd * \sqrt{{( {PDP}_{sim} - {PDP}_{hist} )}^{2}}$$

where Wa, Wb, Wc, and Wd are weight parameters for each measured parameter mismatch, WC is the water cut, Q is the flow rate, PIP is the pump intake pressure, PDP is the pup discharge, the subscript sim represents the virtual measurement, and the subscript hist represents the historical measurement. In some embodiments, the error function may be adjusted to include any number of historical parameters and/or include available sensor measurements along the wellbore or through equipment measurements. For example, the available sensor measurements (including available historical sensor measurements) may include sensors at the ICV that may measure temperature and pressure at the reservoir.

The production digital twin system 312 may calibrate and recalibrate the model 314 based on the mismatch error. In some embodiments, the production estimator 338 may receive the simulated or estimated total production profile and compare it to the measured total production profile. To recalibrate the model 314, the calibrator 330 may tune the model 314 based on the water cut, the PI, and the wellhead pressure (e.g., Pres) to minimize the error function. In this manner, the model 314 may stay tuned or calibrated to the total measured parameters. The calibrator 330 may calibrate the model 314 based on water cut alone, water cut and PI, or water cut, PI, and wellhead pressure.

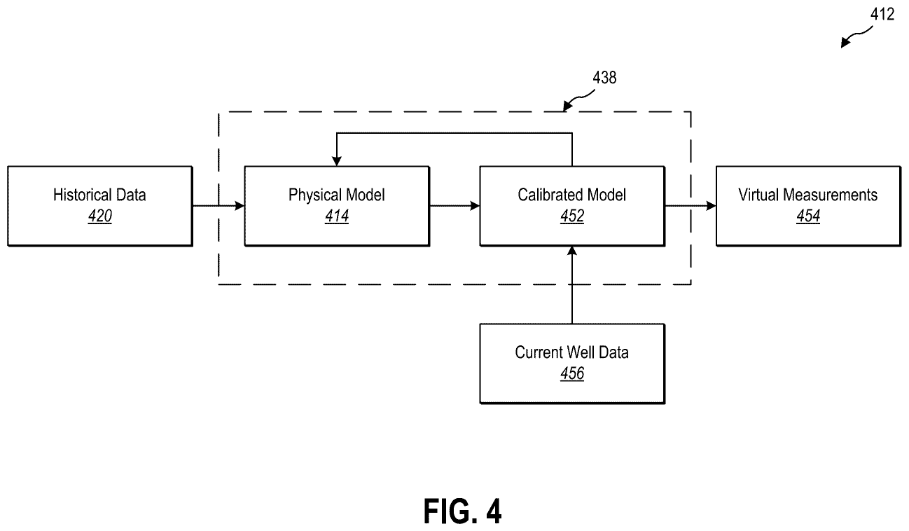

FIG. 4 is a schematic representation of a production digital twin system 412, according to at least one embodiment of the present disclosure. The production digital twin system 412 includes a model 414 of a multilateral well production system. As discussed herein, the model 414 may be calibrated using historical data 420 of the well production system, resulting in a calibrated model 452. The historical data 420 may include historical total production profiles, historical zonal production profiles, historical pump settings, historical valve positions, and so forth.

The production digital twin system 412 may include a production estimator 438. The production estimator 438 may utilize the model 414 and the calibrated model 452 to generate virtual measurements 454. For example, the production estimator 438 may receive current well data 456 (e.g., updated production profiles) for the multilateral well. The production estimator 438 may input the current well data 456 into the calibrated model 452, and the calibrated model 452 may output the virtual measurements 454.

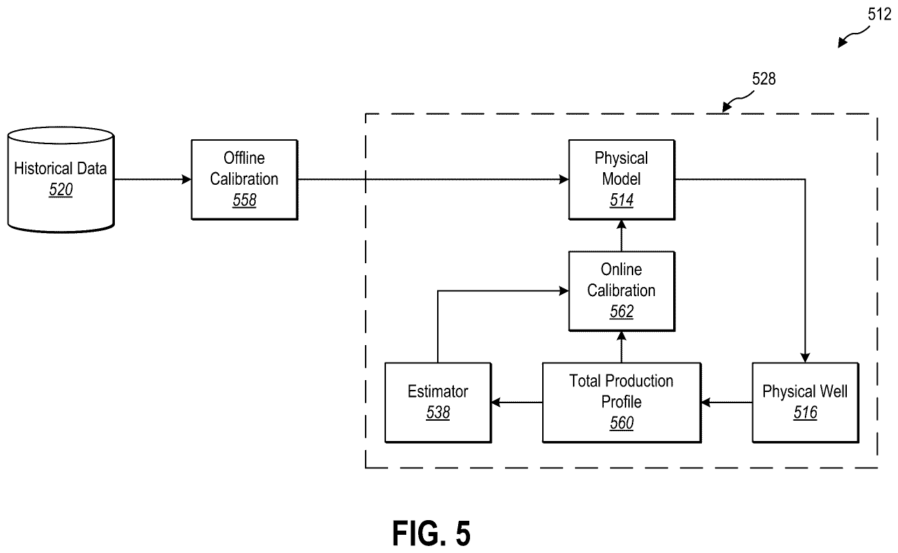

FIG. 5 is a schematic representation of a production digital twin system 512, according to at least one embodiment of the present disclosure. The production digital twin system 512 includes a model 514. As discussed herein, the model 514 may undergo offline calibration 558 using historical data 520 for the multilateral well production system. After the offline calibration 558, the calibrated model 514 may be maintained on an edge network 528 such that estimations and online calibrations are implemented on the edge network 528. The offline calibration 558 may occur on a cloud server, or outside of the edge network 528.

The model 514 may be a representation of a physical wellbore 516, and may estimate characteristics of the physical wellbore 516. Sensors at the physical wellbore 516 may collect a total production profile 560 for the physical wellbore 516. The total production profile 560 may be input into a production estimator 538. As discussed herein, the production estimator 538 may generate virtual measurements, or estimates of the zonal production profiles of the lateral production zones of the multilateral well.

In some embodiments, the production digital twin system 512 may perform an online calibration 562 of the model 514. For example, the production digital twin system 512 may identify when the virtual measurements exceed the historical data 520, such as when a mismatch error exceeds an error threshold. This may result in a recalibrated model 514, which may maintain the representativeness of the model 514 to the physical wellbore 516. As discussed herein, the model 514, sensors measuring the total production profile 560, the production estimator 538, and the online calibration 562 may be located or performed on the edge network 528. This may facilitate improved responsiveness and/or reduced lag for determination of the virtual parameters.

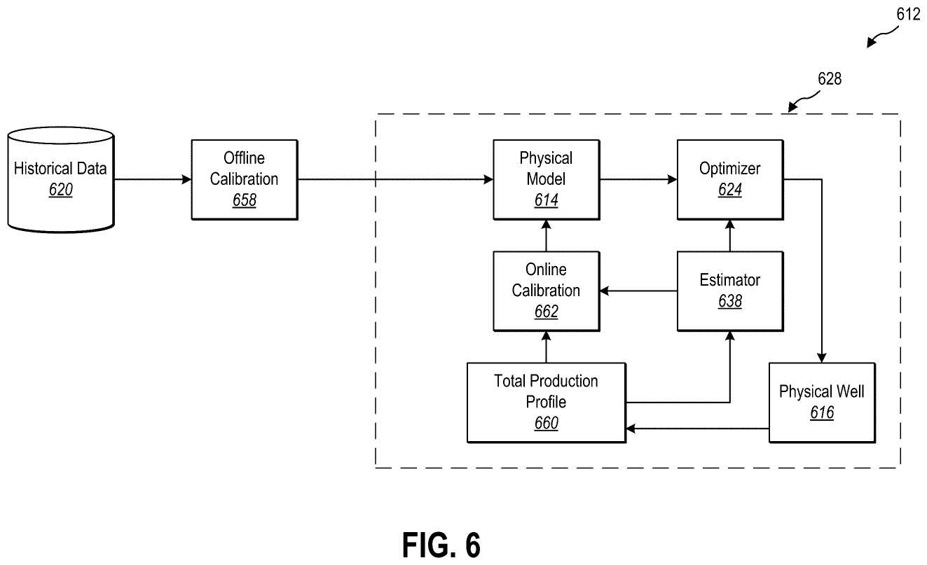

FIG. 6 is a schematic representation of a production digital twin system 612, according to at least one embodiment of the present disclosure. The production digital twin system 612 includes a model 614. As discussed herein, the model 614 may undergo offline calibration 658 using historical data 620 for the multilateral well production system. After the offline calibration 658, the calibrated model 614 may be maintained on an edge network 628 such that estimations and online calibrations are implemented on the edge network 628. The offline calibration 658 may occur on a cloud server, or outside of the edge network 628.

The model 614 may be a representation of a physical wellbore 616, and may estimate characteristics of the physical wellbore 616. Sensors at the physical wellbore 616 may collect a total production profile 660 for the physical wellbore 616. The total production profile 660 may be input into a production estimator 638. As discussed herein, the production estimator 638 may generate virtual measurements, or estimates of the zonal production profiles of the lateral production zones of the multilateral well.

An optimizer 624 may receive the virtual measurements of the zonal production profile from the production estimator 638. Based on the zonal production profile, the optimizer 624 may identify inefficiencies in the operation of the physical wellbore 616. The optimizer 624 may identify a change to the pump settings and/or the valve settings of the ICVs that may improve production or efficiency of the physical wellbore 616. The optimizer 624 may cause the change in the pump settings or the valve settings of the ICVs at the physical wellbore 616, thereby improving operation of the production digital twin system 612.

The optimizer 624 may optimize any combination of properties of the physical wellbore 616. For example, the optimizer 624 may optimize the valve positions of the ICVs. In some examples, the optimizer 624 may optimize the valve positions of the ICVs and the operating state (e.g., pump frequency) of the pump. In some examples, the optimizer 624 may optimize the valve positions of the ICVs, the operating state of the pump, and the wellhead pressure.

The optimizer 624 may perform the optimization by adjusting the properties of the wellbore in the model 614. For example, the optimizer 624 may adjust one or more of the valve position of the ICVs, the operating state of the pump, or the wellhead pressure. The optimizer 624 may identify the change in production profiles. By performing multiple or repeated simulations, the optimizer 624 may optimize the production of the physical wellbore 616.

In some embodiments, the production digital twin system 612 may perform an online calibration 662 of the model 614. For example, the production digital twin system 612 may measure a measured total production profile. The production digital twin system 612 calculate the mismatch error using the measured total production profile and recalibrate the model 614 to minimize the mismatch error. This may result in a recalibrated model 614, which may maintain the representativeness of the model 614 to the physical wellbore 616. As discussed herein, the model 614, sensors measuring the total production profile 660, the production estimator 638, the production estimator 638, and the online calibration 662 may be located or performed on the edge network 628. This may facilitate improved responsiveness and/or reduced lag for determination of the virtual parameters.

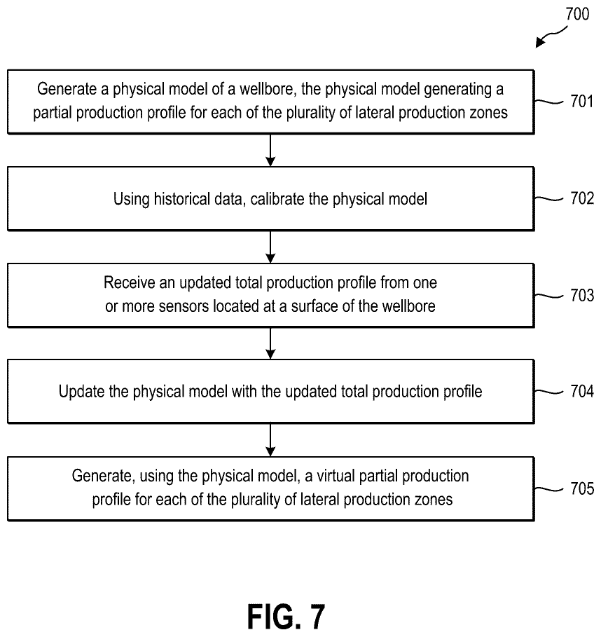

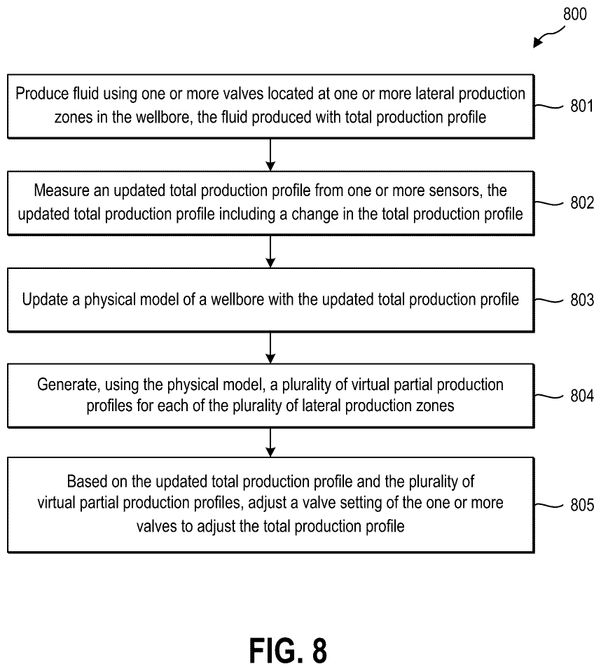

FIG. 7 and FIG. 8, the corresponding text, and the examples provide a number of different methods, systems, devices, and computer-readable media of the production digital twin system. In addition to the foregoing, one or more embodiments can also be described in terms of flowcharts comprising acts for accomplishing a particular result, as shown in FIG. 7 and FIG. 8. FIG. 7 and FIG. 8 may be performed with more or fewer acts. Further, the acts may be performed in differing orders. Additionally, the acts described herein may be repeated or performed in parallel with one another or parallel with different instances of the same or similar acts.

As mentioned, FIG. 7 illustrates a flowchart of a series of acts or a method 700 for modeling wellbore production for a wellbore having a plurality of lateral production zones, according to at least one embodiment of the present disclosure. While FIG. 7 illustrates acts according to one embodiment, alternative embodiments may omit, add to, reorder, and/or modify any of the acts shown in FIG. 7. The acts of FIG. 7 can be performed as part of a method. Alternatively, a computer-readable medium can comprise instructions that, when executed by one or more processors, cause a computing device to perform the acts of FIG. 7. In some embodiments, a system can perform the acts of FIG. 7.

A production digital twin system may generate a model of a wellbore at 701. The model may generate a zonal production profile for each of the plurality of lateral production zones. The zonal production profile is based on a total production profile for the wellbore. The production digital twin system may, using historical data, calibrate the model at 702. The production digital twin system may receive an updated total production profile from one or more sensors located at a surface of the wellbore at 703. The production digital twin system may update the model with the updated total production profile at 704. The production digital twin system may generate, using the model, a virtual zonal production profile based on a total production profile at 705.

As mentioned, FIG. 8 illustrates a flowchart of a series of acts or a method 800 for controlling production in a wellbore, according to at least one embodiment of the present disclosure. While FIG. 8 illustrates acts according to one embodiment, alternative embodiments may omit, add to, reorder, and/or modify any of the acts shown in FIG. 8. The acts of FIG. 8 can be performed as part of a method. Alternatively, a computer-readable medium can comprise instructions that, when executed by one or more processors, cause a computing device to perform the acts of FIG. 8. In some embodiments, a system can perform the acts of FIG. 8.

A production digital twin system may produce fluid using one or more valves located at a plurality of lateral production zones in the wellbore at 801. The fluid is produced with a total production profile. The production digital twin system may measure an updated total production profile from one or more sensors at 802. The updated total profile includes a change in the total production profile. The production digital twin system may update a model of a wellbore with the updated production profile at 803. The production digital twin system may generate, using the model, a plurality of virtual zonal production profiles for each of the plurality of lateral production zones at 804. The production digital twin system may, based on the updated total production profile and the plurality of zonal production profiles, adjust a valve setting of the one or more valves to adjust the total production profile at 805.

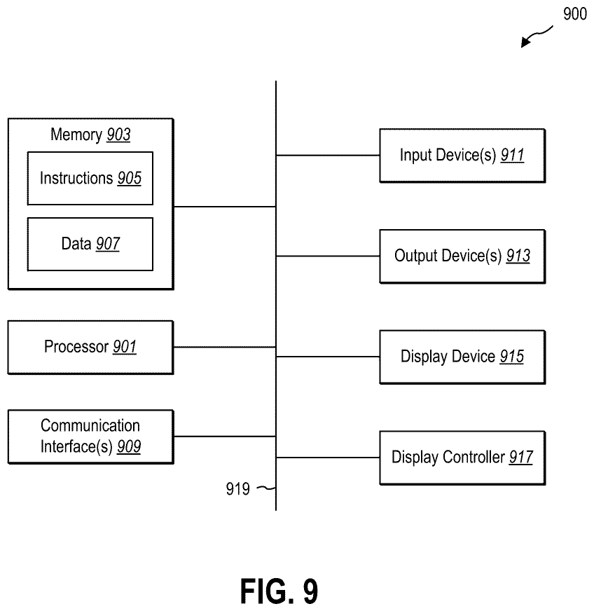

FIG. 9 illustrates certain components that may be included within a computer system 900. One or more computer systems 900 may be used to implement the various devices, components, and systems described herein.

The computer system 900 includes a processor 901. The processor 901 may be a general-purpose single or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 901 may be referred to as a central processing unit (CPU). Although just a single processor 901 is shown in the computer system 900 of FIG. 9, in an alternative configuration, a combination of processors (e.g., an ARM and DSP) could be used.

The computer system 900 also includes memory 903 in electronic communication with the processor 901. The memory 903 may be any electronic component capable of storing electronic information. For example, the memory 903 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 905 and data 907 may be stored in the memory 903. The instructions 905 may be executable by the processor 901 to implement some or all of the functionality disclosed herein. Executing the instructions 905 may involve the use of the data 907 that is stored in the memory 903. Any of the various examples of modules and components described herein may be implemented, partially or wholly, as instructions 905 stored in memory 903 and executed by the processor 901. Any of the various examples of data described herein may be among the data 907 that is stored in memory 903 and used during execution of the instructions 905 by the processor 901.

A computer system 900 may also include one or more communication interfaces 909 for communicating with other electronic devices. The communication interface(s) 909 may be based on wired communication technology, wireless communication technology, or both. Some examples of communication interfaces 909 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 900 may also include one or more input devices 911 and one or more output devices 913. Some examples of input devices 911 include a keyboard, mouse, microphone, remote control device, button, joystick, trackball, touchpad, and lightpen. Some examples of output devices 913 include a speaker and a printer. One specific type of output device that is typically included in a computer system 900 is a display device 915. Display devices 915 used with embodiments disclosed herein may utilize any suitable image projection technology, such as liquid crystal display (LCD), light-emitting diode (LED), gas plasma, electroluminescence, or the like. A display controller 917 may also be provided, for converting data 907 stored in the memory 903 into text, graphics, and/or moving images (as appropriate) shown on the display device 915.

The various components of the computer system 900 may be coupled together by one or more buses, which may include a power bus, a control signal bus, a status signal bus, a data bus, etc. For the sake of clarity, the various buses are illustrated in FIG. 9 as a bus system 919.

The embodiments of production digital twin system have been primarily described with reference to wellbore drilling operations; the production digital twin system described herein may be used in applications other than the drilling of a wellbore. In other embodiments, production digital twin systems according to the present disclosure may be used outside a wellbore or other downhole environment used for the exploration or production of natural resources. For instance, production digital twin systems of the present disclosure may be used in a borehole used for placement of utility lines. Accordingly, the terms “wellbore,” “borehole” and the like should not be interpreted to limit tools, systems, assemblies, or methods of the present disclosure to any particular industry, field, or environment.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method for modeling wellbore production for a wellbore having a plurality of lateral production zones, the method comprising:
generating a model of a wellbore;
using historical data, calibrating the model;
receiving an updated total production profile from one or more sensors located at a surface of the wellbore;
updating the model with the updated total production profile; and
generating, using the model, a virtual zonal production profile for each of the plurality of lateral production zones, the virtual zonal production profile based on a total production profile.

2. The method of claim 1, wherein the wellbore includes a plurality of inflow control valves (ICVs), each of the plurality of lateral production zones associated with one of the plurality of ICVs, each of the plurality of ICVs having a plurality of valve settings, and further comprising, based on the virtual zonal production profile, adjusting one of the plurality of valve settings for at least one of the plurality of ICVs.

3. The method of claim 2, wherein the historical data includes the plurality of valve settings for the plurality of lateral production zones.

4. The method of claim 2, further comprising optimizing the wellbore production based on the plurality of valve settings.

5. The method of claim 1, wherein calibrating the model includes providing an initial estimate for parameters of the plurality of lateral production zones.

6. The method of claim 5, wherein the parameters include at least one of a partial water cut, a partial productivity index, and a reservoir pressure.

7. The method of claim 1, wherein calibrating the model includes optimizing the model for at least one of water cut, production index, or pressure.

8. The method of claim 1, further comprising generating a mismatch error for the virtual zonal production profile.

9. The method of claim 8, further comprising, recalibrating the model using measured zonal production profiles to minimize the mismatch error.

10. The method of claim 1, wherein receiving the total production profile includes receiving at least one of intake pressure, discharge pressure, total flow rate, or total water cut.

11. The method of claim 1, wherein the virtual zonal production profile includes at least one of partial upstream ICV pressure, partial downstream ICV pressure, partial flow rate, or partial water cut.

12. The method of claim 1, wherein the model is located on an edge network.

13. A method for controlling production in a wellbore, the method comprising:
producing fluid using one or more valves located at a plurality of lateral production zones in the wellbore, the fluid produced with total production profile;
measuring an updated total production profile from one or more sensors, the updated total production profile including a change in the total production profile;
updating a model of a wellbore with the updated total production profile;
generating, using the model, a plurality of virtual zonal production profiles for each of the plurality of lateral production zones; and
based on the updated total production profile and the plurality of virtual zonal production profiles, adjusting a valve setting of the one or more valves to adjust the total production profile.

14. The method of claim 13, where the change in one or more production conditions is a change in water cut.

15. The method of claim 14, where the change in water cut is a gradual water cut increase.

16. The method of claim 15, where the change in water cut is an acute water cut change.

17. The method of claim 13, further comprising attributing the change to a particular lateral production zone.

18. The method of claim 13, wherein the model is located on an edge network.

19. A system, comprising:
a processor and memory, the memory including instructions that cause the processor to:
generate a model of a wellbore;
using historical data, calibrate the model;
receive an updated total production profile from one or more sensors located at a surface of the wellbore;
update the model with the updated total production profile; and
generate, using the model, a virtual zonal production profile for each of a plurality of lateral production zones, the virtual zonal production profile based on a total production profile.

20. The system of claim 19, wherein the wellbore includes a plurality of inflow control valves (ICVs), each of the plurality of lateral production zones associated with one of the plurality of ICVs, each of the plurality of ICVs having a plurality of valve settings, and wherein the instructions further cause the processor to, based on the virtual zonal production profile, adjusting one of the plurality of valve settings for at least one of the plurality of ICVs.
